(19) United States
(12) Patent Application Publication
(10) Pub. No.: US 2020/0370713 A1
(43) Pub. Date: Nov. 26, 2020

(54) LENS ASSEMBLY FOR LED LIGHT FIXTURE

(71) Applicant: SUR-SEAL CORPORATION, Cincinnati, OH (US)

(72) Inventor: Craig D. RALEIGH, Burlington, WI (US)

(21) Appl. No.: 15/929,758

(22) Filed: May 20, 2020

Related U.S. Application Data
(60) Provisional application No. 62/850,313, filed on May 20, 2019.

(51) Int. Cl. F21K 9/69; H01L 33/58; H01L 33/54; H01L 25/13; F21K 9/90

(52) U.S. Cl. CPC F21K 9/69; H01L 33/58; F21Y 2115/10; H01L 25/13; F21K 9/90; H01L 33/54

(57) ABSTRACT

An LED lens assembly includes a bezel, and at least one secondary lens and a gasket that are molded together onto the bezel. At least one of the secondary lens and the gasket are molded from a single shot of injection molding material in an injection molding process.

### CROSS-REFERENCE TO RELATED APPLICATION

This application claims priority to and the benefit of pending U.S. Provisional Application No. 62/850,313 filed May 20, 2019, which is incorporated by reference herein in its entirety.

### BACKGROUND

Light Emitting Diode (LED) light fixtures (alternately referred to as “LED light engines”) are becoming commonplace as utilities, governments, businesses, and individuals seek methods of decreasing energy costs. LED light fixtures have the advantage of decreased energy usage when compared to traditional light sources such as incandescent, metal halide, and high-pressure sodium light sources. Additionally, with projected lives of 100,000 hours or more, they provide the ideal replacement for applications were maintenance costs are high, such as in street lighting applications.

A typical LED light fixture includes an LED light source mounted within a fixture housing. The LED light source comprises a single LED chip or a small grouping of LED chips. A primary lens (also referred to as a “primary optic”) is often formed over and otherwise encases each LED chip to protect the LED chip from environmental damage and/or contamination. A secondary lens (also referred to as a “secondary optic”) is coupled to the housing and arranged to receive, diffuse, and direct light emitted from the LED light source. A gasket is commonly used to generate a seal between the housing and the secondary lens. Creating a sealed environment is particularly important when the fixture will be exposed to harsh environments, such as when the fixture is used for outdoor street lighting. Some LED light fixtures also include a bezel that helps secure the secondary lens and the gasket to the housing.

The secondary lens, the gasket, and the bezel are collectively referred to as a “lens assembly” and are commonly made from plastics or polymers. Traditionally, the secondary lens, the gasket, and the bezel are formed as separate components that must be preassembled prior to securing the lens assembly to the housing. To reduce assembly costs and preassembly of the various component parts, lens assemblies in recent years have been fabricated as a one-piece component part. The one-piece lens assembly can be formed, for example, via a single shot in an injection molding process.

Creating a one-piece lens assembly in this manner, however, has its own challenges. For example, the secondary lens, the gasket, and the bezel when formed from a single shot will be of the same type of material, and this material will be of a type suitable for optics, such as the secondary lens. Thus, the bezel component of this type of lens assembly will be made of an optics material and the resulting lens assembly will exhibit a degree of flexibility. Accordingly, this type of lens assembly lacks rigidity and is not suitable for use with many types of LED light fixtures.

### SUMMARY

Embodiments herein are directed towards an LED lens assembly comprising a bezel and a molded component, wherein the molded component includes at least one secondary lens and a gasket, and wherein the molded component is formed over the bezel with a single shot. The molded component may be formed from a liquid silicone rubber material. The bezel may be formed from a thermoplastic material. The at least one secondary lens may be interlocking with the bezel.

In some embodiments, the at least one secondary lens may include an exit surface protruding along an axis from a void in an outer surface of the bezel. In these embodiments, the exit surface may be symmetrical about the axis along which the at least one secondary lens extends beyond the outer surface of the bezel; and in these latter embodiments, the exit surface may include a dimple.

In some embodiments, the at least one secondary lens may include an exit surface protruding along an axis from a void in an outer surface of the bezel. In these embodiments, the bezel may include a locking flange extending around the void, and the at least one secondary lens includes an outer locking portion and an inner locking portion that sandwich the locking flange. In some of these embodiments, the outer locking portion and the inner locking portion may extend outward from the secondary lens, radial and perpendicular to the axis. In some of these embodiments, the outer locking portion and the inner locking portion may be spaced apart from each other along the axis. In some of these embodiments, the outer locking portion may extend radially from a base of the exit surface; and in some of these embodiments the inner locking portion is spaced along the axis relative to the outer locking portion so that the outer locking portion interposes the exit surface and the inner locking portion. In some of these embodiments, the at least one secondary lens includes at least one structural portion extending through the locking flange of the bezel and interconnecting the upper and inner locking portions of the secondary lens.

In some embodiments, the molded component is co-molded to the bezel. In some embodiments, the molded component is over-molded onto the bezel. In some embodiments, the secondary lens is optically clear.

Other embodiments herein are directed towards a method of fabricating an LED lens assembly, comprising forming a frame, and molding at least one secondary lens and a gasket to the frame, wherein the at least one secondary lens and the gasket are made of a single shot of material. In some embodiments, molding the gasket and the at least one secondary lens to the frame comprises co-molding the gasket and the at least one secondary lens to the frame. In some embodiments, molding the gasket and the at least one secondary lens comprises over-molding the gasket and the at least one secondary lens to the secondary lens.

Other embodiments herein are directed towards an LED light fixture, comprising a housing defining an interior, an LED light source arranged within the interior and including one or more LED chips, wherein each LED chip is encapsulated by a primary lens, a bezel coupled to the housing, and at least one secondary lens and a gasket molded to the bezel, wherein the at least one secondary lens and the gasket is made of a material provided in a single shot of an injection molding process.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is an isometric view of an example LED light fixture that may incorporate one or more principles of the present disclosure.

FIG. 2 is a cross-sectional side view of the LED light fixture of FIG. 1.

FIGS. 3A and 3B are isometric top and bottom views, respectively, of an exemplary LED lens assembly, according to one or more embodiments, and FIG. 3C is an exploded isometric view of the LED lens assembly of FIG. 3A.

FIGS. 4A and 4B are top and bottom views, respectively, of the frame of FIGS. 3A-3C without the secondary lenses and the gasket molded thereto, and FIG. 4C is a cross-section of the frame along section line 4-4 in FIGS. 4A and 4B.

FIG. 5 is a detailed view of one of the secondary lenses and a portion of the gasket of FIG. 3C that is moldable within the frame of FIGS. 4A and 4B.

FIG. 6A is a top isometric cross-sectional view of the LED lens assembly along section line 6-6 in FIG. 3A. FIG. 6B is a bottom isometric cross-sectional view of the LED lens assembly along section line 6′-6′ in FIG. 3B.

FIG. 7A is a top view of the LED lens assembly of FIGS. 3A and 3B; whereas FIG. 7B is a partial side cross-sectional view of the LED lens assembly along section line 7-7 in FIG. 7A, and FIG. 7C is a partial side cross-sectional view of the LED lens assembly along section line 7′-7′ in FIG. 7A.

### DETAILED DESCRIPTION

The present disclosure is related to LED light fixtures and, more particularly, to lens assemblies used in LED light fixtures and methods of manufacturing the lens assemblies.

The embodiments discussed herein describe an LED lens assembly having a bezel, an optic, and a gasket. The optic and gasket are integral with each other. The gasket and optic may be over-molded or co-molded to the bezel with a single shot of material during an injection molding process. In one embodiment, for example, the gasket and optic may be made of a silicone and the bezel is a thermoplastic.

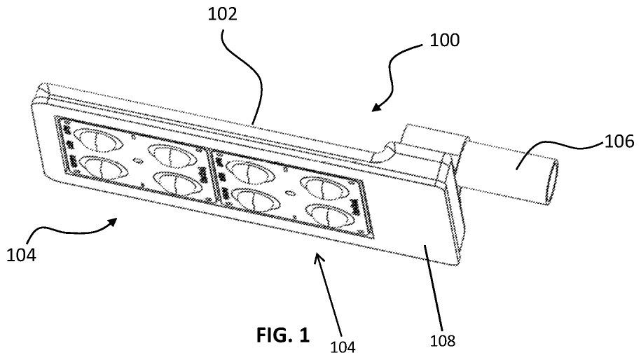

FIG. 1 is an isometric view of an example LED light fixture 100 that may incorporate one or more principles of the present disclosure. As illustrated, the LED light fixture 100 includes a housing 102, a lens assembly 104 coupled to the housing 102, and a support 106 used to support the LED light fixture 100 in a desired orientation. In operation, the LED light fixture 100 can be used as an indoor or an outdoor luminaire. In the illustrated embodiment, the LED light fixture 100 includes a pair of the LED lens assemblies 104. Here, a face plate 108 of the housing 102 is provided to permit mounting (incorporation) of two (2) of the LED lens assemblies 104 within the LED light fixture 100. However, in other examples, the face plate 108 may be configured to permit utilization of more or less than two (2) of the LED lens assemblies 104.

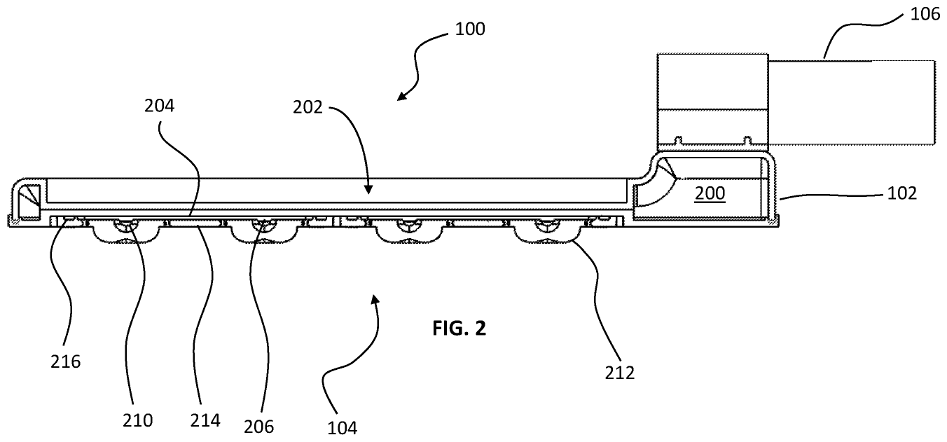

FIG. 2 is a cross-sectional side view of the LED light fixture 100. As illustrated, the housing 102 defines an interior 200 and an LED light source 202 is mounted to the housing 102 within the interior 200. The LED light source 202 may include a circuit board 204 and one or more LED chips 206 operatively coupled to the circuit board 204. The circuit board 204 may be coupled to the housing 102 with a bracket (obscured from view) or another suitable form of attachment.

Each LED chip 206 may have a primary lens 210 (alternately referred to as a “primary optic”) formed thereon or otherwise encapsulating the corresponding LED chip 206. The primary lens 210 serves to protect the corresponding LED chip 206 from environmental damage or contamination. While six LED chips 206 and corresponding primary lenses 210 are shown in FIG. 2, more or less than six may be employed, without departing from the scope of the disclosure.

The lens assembly 104 includes a plurality of secondary lenses 212 (alternately referred to as a “secondary optic”), a frame 214, and a gasket 216. In the illustrated example, the secondary lenses 212 are supported and maintained by the frame 214. The secondary lenses 212 and the gasket 216 may be formed with a single shot during an over-molding process. Thus, as described below, the frame 214 may include voids corresponding with the gasket 216 and each of the secondary lenses 212, as well as a network of runners interconnecting these voids and arranged for molding the gasket 216 and the secondary lenses 212 simultaneously with a single shot. Moreover, the gasket 216 and the secondary lenses 212 may be over-molded on to the frame 214 having sufficient rigidity support and maintain the secondary lenses 212 in a certain orientation or position relative to the LED light source 202, and also to support and maintain the gasket 216 in a certain orientation or position relative to the housing 102 to create and maintain a seal. Accordingly, the secondary lenses 212 and the gasket 216 may be injection molded with a single shot in an over-molding (or insert molding) process; however, multi-shot injection molding could be used where the thermoplastic substrate (i.e., the bezel or the frame 214) is injection molded in the first shot and the gasket 216 and the optics (i.e., the secondary lenses 212) are injection molded in a second shot.

The secondary lenses 212 are optics configured to refract or otherwise direct light from the LED chips 206. Each of the secondary lenses 212 includes an entrance refraction surface and an exit refraction surface. The entrance refraction surface of the secondary lenses 212 is located on an interior of the lens assembly 104, and defines an interface where light initially emitted from the LED chip 206 enters the secondary lens 212. Thus, the entrance refraction surface is configured to receive the primary lens 210, and in some examples, the entrance refraction surface may be designed to control the light exiting the primary lens 210. The exit refraction surface of the secondary lens 212 is on the exterior of the lens assembly 104, and defines the interface at which light exits the secondary lens 212 and enters the external environment in which the LED light fixture 100 utilized. In some examples, the exit refraction surface may be designed to control the light exiting the primary lens 210. Thus, as will be appreciated, the light pattern ultimately emitted from the LED light fixture 100 depends on numerous characteristics of the LED light fixture 100, including but not limited to the geometry of the entrance refraction surface and the exit refraction surface. Accordingly, the entrance refraction surface and/or the exit refraction surface may have various geometries depending on the light pattern desired to be output from the LED light fixture 100 in a particular end use application. In the illustrated example, the exit refraction surface of each of the secondary lenses 212 is symmetrical and semi-circular in shape; however, one or more of the secondary lenses 212 may have a different shape.

The frame 214 holds or supports the secondary lenses 212 over in a particular orientation relative to the LED light source 202 in the interior 200 of the housing 102. In the illustrated embodiment, the frame 214 positions and holds the secondary lens 212 over an opening in the housing 102 so that each of the secondary lenses 212 corresponds with one of the primary lenses 210 and one of the LED chips 206 associated therewith. Though, there need not be a 1:1:1 correspondence between the LED chips and the primary lenses 210 and the secondary lenses 212. Also in the illustrated embodiment, the frame 214 is configured as a bezel that is removably coupled to the housing 102 with one or more mechanical fasteners (obscured from view). The gasket 216 interposes the frame 214 and the housing 102 to seal the interior 200 of the housing 102. The gasket 216 may prevent contamination of the interior 200, such as by preventing the ingress of moisture and dust. In some embodiments, the gasket 216 is integrally formed with one or more of the secondary lenses 212.

As illustrated, the frame 214 positions the secondary lenses 212 in a plane that is offset from the LED light source 202. The space and distance separating the secondary lenses 212 from the LED light source 202 allows full distribution of the light emitted from each of the LED chips 206 to their corresponding secondary lenses 212. More specifically, the secondary lenses 212 are arranged relative to the LED light source 202 and designed to direct the light produced by the LED chip(s) 206 to an area external the LED light fixture 100 where the light is needed, and otherwise away from areas where it is not needed or might otherwise cause light trespass. Light trespass occurs when light spills into areas where it is not wanted. For example, commercial developments in residential areas often design outdoor lighting systems to prevent light from spilling or “trespassing” onto neighboring residential properties. In operation, the secondary lens 212 may be designed to create a very intense, but small light pattern, to create a broad and diffused light pattern, to truncate the light to prevent light trespass, or to achieve any combination of those objectives.

In the illustrated examples, each lens assembly 104 is provided as a unitary component having a single array of four (4) secondary lenses 212 arranged in two rows and two columns. Thus, the illustrated lens assembly 104 includes four secondary lenses 212. The lens assembly 104 may be differently arranged, however. For example, either or both lens assemblies 104 may have more or less than one array of secondary lenses 212 arranged two-by-two, without departing from the present disclosure. For example, the lens assembly 104 may include a single row of various numbers of secondary lenses 212, aligned linearly or non-linearly, or arranged in any number of other patterns as may be desirable due to space limitations and/or to maximize illumination. Moreover, the array(s) may have different patterns of secondary lenses 212 and, in examples where the lens assembly includes two (2) or more arrays, the separate arrays may have the same or different patterns of secondary lenses 212.

The frame 214 may be made of a metal, a hard plastic, or any other material that is sufficiently rigid to secure the secondary lenses 212 to the housing 102 (FIGS. 1 and 2). In applications where the frame 214 is made of a metal, the frame 214 may be stamped from sheet metal in a die. Suitable metals for the frame 214 include, but are not limited to, aluminum (or cast aluminum), stainless steel, copper, brass, or any combination thereof. In applications where the frame 214 is made of a plastic or thermoplastic, the frame 214 may be injection molded. Suitable materials for the frame 214 include, but are not limited to, an acrylic, a polycarbonate, a silicone, or another suitable elastomer, polymer or thermoplastic.

The secondary lenses 212 may be made of an optical (i.e., including but not limited to, transparent or translucent) material that is injection molded. Suitable optical materials for the secondary lenses 212 include, but are not limited to, an acrylic (for example, acrylate polymer such as poly(methyl methacrylate), alicyclic acrylate, etc.), a polycarbonate, a polystyrene, cyclic olefins, a liquid silicone rubber (LSR), a polyester, polyetherimide, NAS (styrene acrylic copolymer), SAN (styrene acrylonitrile), glass, optical ceramics, or another optical material including, but not limited to, thermoplastic, thermosetting (collectively organic) or inorganic materials. In at least one embodiment, however, the secondary lenses 212 may be made of glass. The gasket 216 may also be injection molded and made of a silicone or another type of material capable of forming a fluid-tight seal. In some examples, the secondary lenses 212 and the gasket 216 are molded from a single shot in an over-molding process, an insert molding process, or a co-molding process.

Traditionally, the secondary lens 212, the frame 214, and the gasket 216 would be made individually and subsequently assembled together for joint coupling to the housing 102 (FIGS. 1 and 2). As described herein, however, the component parts of the LED lens assembly 104 may be fabricated as a one-piece structure. As used herein with reference to the LED lens assembly 104, the term “one-piece structure” refers to the secondary lenses 212, the bezel 214, and the gasket 216 forming an integral structure assembled via a molding process (e.g., an over-molding process, a co-molding process, a multi-component injection molding process, etc.) with sufficient rigidity to support the secondary lenses 212 and the gasket 216 in suitable positions and orientations for their functions.

For example, the secondary lens 212 and the gasket 216 may be formed as a one-piece structure with separate shots during a co-molding process. In such embodiments, the secondary lens 212 and the gasket 216 are formed during a single injection molding process, with the secondary lens 212 formed through a first injection molding shot, and the gasket 216 subsequently formed through a second injection molding shot. This process can be facilitated with a single mold or with multiple molds and, as with the above-described over-molding process, the co-molded material of the gasket 216 forms a bond with the material of the secondary lens 212. Moreover, as will be appreciated, the co-molding process may also be swapped (reversed), where the gasket 216 is instead formed via the first shot and the secondary lens 212 is then formed on the gasket 216 via a second shot, without departing from the scope of the disclosure.

In one example, the secondary lenses 212 and the gasket 216 may be formed as a single molded component (i.e., a unitary component) via an over-molding process. In such embodiments, the frame 214 may be formed in a first mold during a first injection molding process. The secondary lenses 212 and the gasket 216 may then be molded onto the frame 214 during a second injection molding process. In some cases, following the first injection molding process, the frame 214 may be transferred to a second mold to undertake the second injection molding process. In other cases, however, the frame 214 may remain, and a portion of the first mold may be modified to facilitate the second injection molding process. In either case, the over-molded material of the secondary lenses 212 and the gasket 216 forms a bond with the material of the frame 214 and thereby creates a one-piece structure. As will be appreciated, however, the process may be swapped (reversed), where the secondary lenses 212 and the gasket 216 is instead formed first and the frame 214 is over-molded onto the molded component comprised of the secondary lenses 212 and the gasket 216, without departing from the scope of the disclosure.

In some examples, the LED lens assembly 104 is fabricated via a multi-component injection molding process. Multi-component injection molding is a process that includes over-molding LSR directly onto a thermoplastic substrate immediately after the thermoplastic substrate has been molded, in the same mold and with the same injection molding machine. This process allows for the integration of different materials into a single component, while simultaneously reducing or eliminating the need for post-molding assembly operations and equipment. For example, the frame 214 may be a molded thermoplastic member formed with a first shot (of thermoplastic material) forced into a mold. During this first shot, a network of voids and runner slots are formed or molded into the frame 214. After molding the frame 214, a second shot (of LSR material) is forced into the mold to form the secondary lenses 212 and the gasket 216. During this second shot, LSR is fed into and through the mold to fill the network of voids and runner slots previously formed in the frame 214. Thus, in this example the secondary lenses 212 and the gasket 216 are molded together as a single molded component with a single, second shot of a multi-component injection molding process, and, simultaneously, this single molded component of LSR is molded over the frame 214 to fabricate (or assemble) the LED lens assembly 104 as a one-piece structure. The over-molded material of the secondary lenses 212 and the gasket 216 forms a bond with the material of the frame 214 onto which they are over-molded, thereby creating a one-piece structure.

The above-described over-molding and co-molding processes, however, do not come without their challenges, especially where one or more of the secondary lenses 212, the gasket 216, and the frame 214 are made of different materials that exhibit differing glass transition (i.e., softening) and curing temperatures. For example, the frame 214 may be made of a thermoplastic (e.g., polycarbonate) that exhibits a glass transition temperature of about 296.6° F. (147° C.), and the optics of the secondary lenses 212 and the gasket 216 may be made of a traditional platinum curable silicone (e.g., ultra clear or optical LSR) that is cured at temperatures ranging between about 248° F. (120° C.) to 356° F. (180° C.). However, when over molding onto a thermoplastic, such as polycarbonate, the heat deflection temperature of the thermoplastic may be sufficiently low that the clamp pressure of the tool can start to indent, mar, and/or distort the surfaces of the thermoplastic material. The heat deflection temperature (or the heat distortion temperature) of the particular thermoplastic material is the temperature at which the thermoplastic deforms under load, and the heat deflection temperature is dependent on load but generally less than the material's glass transition temperature. To properly cure the secondary lenses 212 and the gasket 216 during an over-molding or co-molding process, the frame 214 will be subjected to temperatures exceeding the glass transition temperature of the thermoplastic, which might result in abnormalities and/or defects developing in the frame 214.

According to the present disclosure, and to mitigate the adverse effects described above, the secondary lenses 212 and the gasket 216 may be made of a material that is curable (catalyzed) using low temperature electromagnetic radiation. As used herein, the term “electromagnetic radiation” refers to ultraviolet (UV) light, visible light, radio waves, microwave radiation, infrared and near-infrared radiation, X-ray radiation, gamma ray radiation, or any combination thereof. As used herein, the term “low temperature electromagnetic radiation” refers to electromagnetic radiation emitted, dispersed, or otherwise absorbed at a temperature of around 185-200° F. or below. The glass transition temperature (Tg) of atactic PMMA is around 105° C. (221° F.). The Tg values of many commercial grades of PMMA range from 85 to 165° C. (185 to 329° F.); the range is wide due to the vast number of commercial compositions which are copolymers with co-monomers other than methyl methacrylate. In at least one embodiment, the low temperature electromagnetic radiation may comprise UV light transmitted or emitted at ambient (room) temperature, or typically between about 59° F. (15° C.) and about 77° F. (25° C.), but as high as approximately 100 to 110° F. Thus, the secondary lenses 212 and the gasket 216 may be made of a material that is curable using low temperature electromagnetic radiation. Suitable materials that may be curable using low temperature electromagnetic radiation include, but are not limited to, UV curable silicone rubber, UV curable polyester, UV curable PMMA, other UV curable optical materials, and any combination thereof. In some embodiments, the material for the secondary lenses 212 and the gasket 216 may be cured at or near room temperature upon being exposed to UV light. This may prove advantageous in mitigating any adverse effects on the frame that might otherwise occur with materials requiring elevated cure temperatures. Moreover, in some examples, the material of the secondary lenses 212 and the gasket 216 is cured through the frame 214. For example, the frame 214 may be made from a material that is optically clear or translucent, such as an acrylic, a polycarbonate, liquid silicone rubber (LSR), a polyester, or glass, etc., and then the material for the secondary lenses 212 and the gasket 216 may be cured by passing the UV light through the frame 214, if needed. In some examples, a chemical primer may be utilized to assist in bonding (locking) the material of the secondary lenses 212 and the gasket 216 (e.g., LSR) to the frame 214. In some examples, a surface treatment process, including but not limited to corona/plasma treating, may be utilized to prepare the surface, which treatment increases the surface energy of the substrate to thereby facilitate bonding. In some examples, primers and surface treatments are both utilized to assist in bonding, or either may be utilized to assist in bonding.

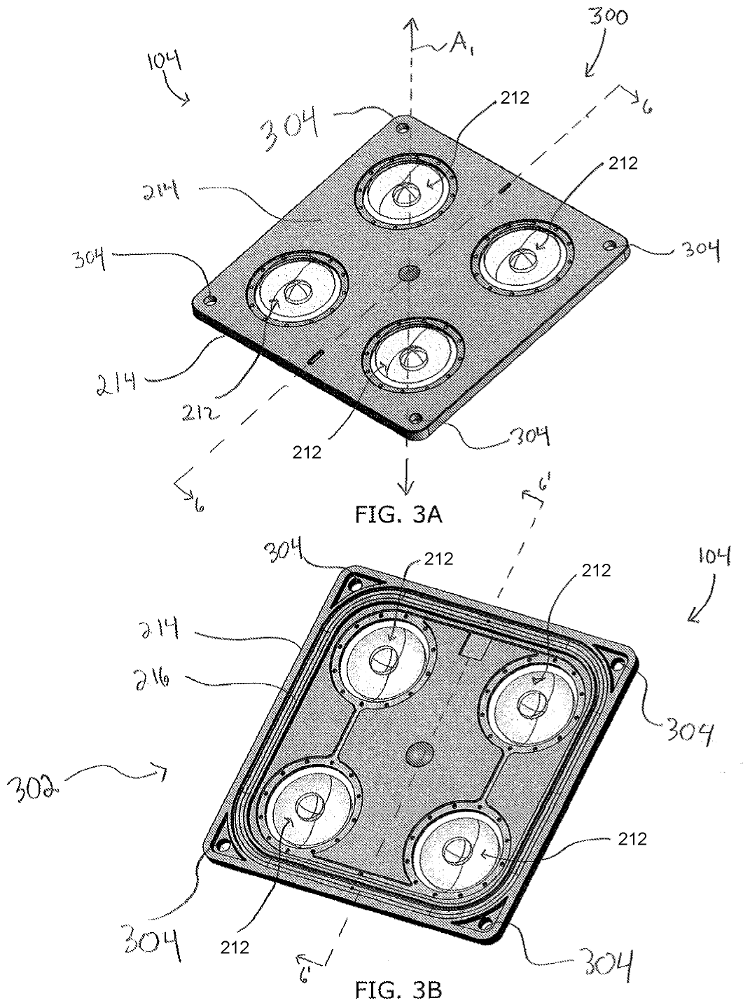

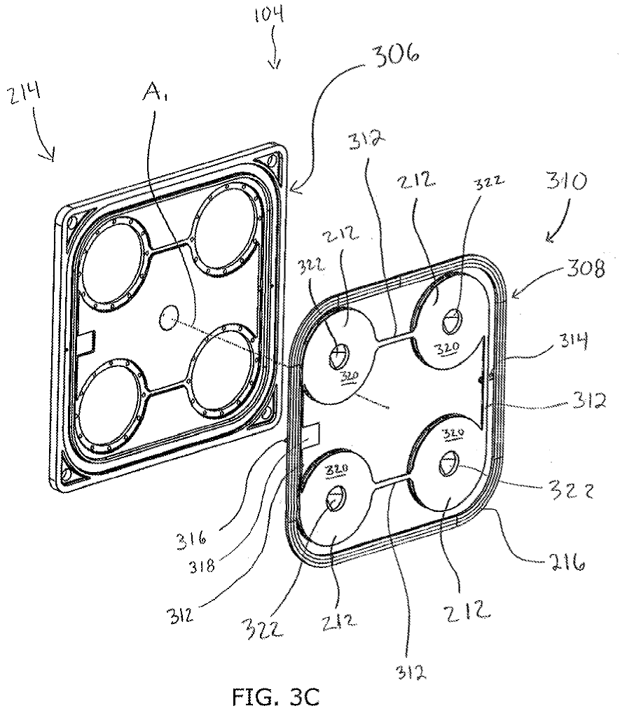

FIGS. 3A and 3B are isometric top and bottom views, respectively, of the LED lens assembly 104, according to one or more embodiments. FIG. 3A illustrates an outer side 300 of the lens assembly 104, whereas FIG. 3B illustrates an inner side 302 of the lens assembly 102. The LED lens assembly 104 includes an axis A₁ that, in the illustrated example, is substantially normal to the outer side 300 and inner side 302. As illustrated, a plurality of fastener holes 304 may be defined the frame 214 for receiving the mechanical fasteners used to secure the LED lens assembly 104 to the housing 102 (FIGS. 1 and 2). The fastener holes 304 in the illustrated example are oriented substantially parallel to the axis A₁. In the illustrated example, the fastener holes 304 are only defined in the frame 214 at locations thereon that are positioned outwardly of or to the exterior of the gasket 216. However, the fastener holes 304 may also extend through the gasket 216 or through other pieces of material connected to the gasket. Moreover, while FIGS. 3A and 3B depict an example where the LED lens assembly 104 includes an array of four distinct secondary lenses 212 suspended in the frame 214, it is contemplated herein that the LED lens assembly 104 may have more or less than four distinct secondary lenses 212, including an embodiment with a single secondary lens 212, without departing from the scope of the disclosure.

FIG. 3C is an exploded isometric view of the LED lens assembly 104 of FIGS. 3A and 3B. In particular, FIG. 3C illustrates the secondary lenses 212 and the gasket 216 as they would appear after being molded to the frame 214 and curing, except outside of the frame 214, which is shown spaced apart therefrom along the axis A₁. Also, FIG. 3C shows an entry side 306 of the frame 214 into which the secondary lenses 212 will extend after molding and an entry side 308 of the secondary lenses 212 that would be in close proximity with the interior 200 when the LED lens assembly 104 is assembled onto the housing 102 as the LED light fixture 100.

As shown, a network or system of runners exists, interconnecting the secondary lenses 212 and the gasket 216 as a unitary component 310. The unitary component 310 may be formed or molded from a single shot of material in an injection molding operation and, therefore, is sometimes referred to herein as the “molded component.” The gasket 216 surrounds or encloses the secondary lenses 212, and several pieces of cured injection molding material extend between pairs of the secondary lenses 212 and between the gasket 216 and the secondary lenses 212. As illustrated, a system of optic runners 312 extends between neighboring pairs of the secondary lenses 212. Also, a split runner 314 interconnects the gasket 216 and the secondary lenses 212. In the illustrated example, the split runner 314 extends between the gasket 216 and one of the optic runners 312, thereby connecting the gasket 216 and the secondary lenses 212 as the unitary component 310. In addition, overflow systems may be incorporated to accommodate excess material unneeded to sufficiently form the secondary lenses 212 and the gasket 216. In the illustrated example, a gasket overflow 316 is shown extending from the gasket 216 and an optic overflow 318 is shown extending from one of the optic runners 312. The gasket and optic overflows 316,318 may result from excess material flow during injection molding and/or venting of any trapped gas.

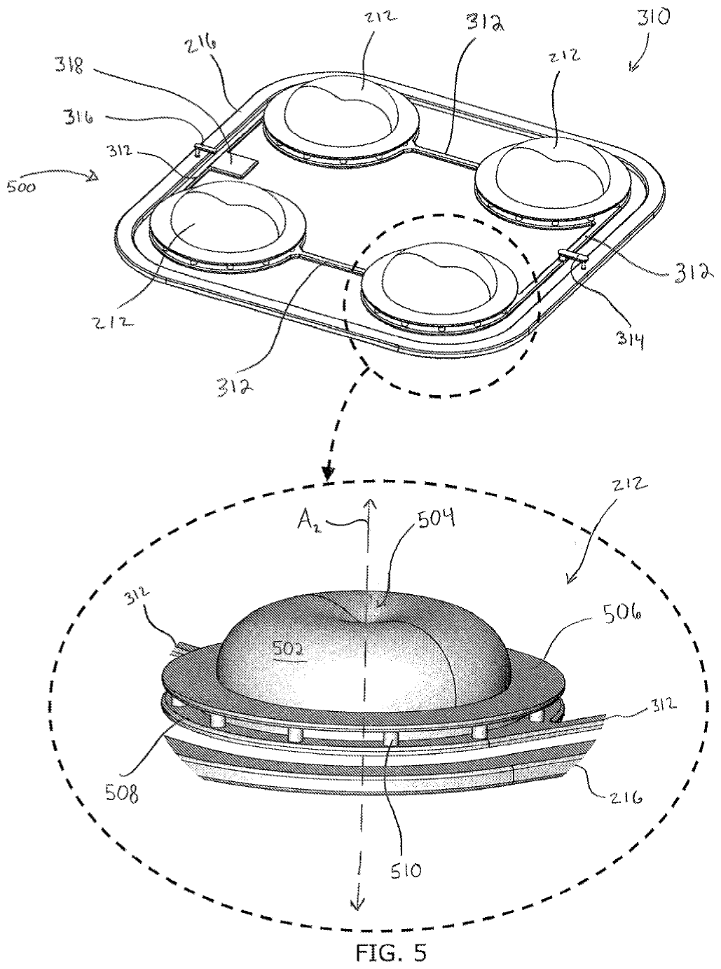

Each of the secondary lenses 212 includes an entry face 320 oriented on the entry side 308 of the unitary component 310. Also, each of the secondary lenses 212 includes an entrance 322 formed into its entry face 320. The entry faces 320 and their associated entrances 322 may have various geometries, depending on the desired output illumination. In embodiments incorporating two or more of the secondary lenses 212, the entry faces 320 and corresponding entrances 322 of each of the secondary lenses 212 may have the similar geometries; however, in other examples, one or more may have a different geometry. In the illustrated example, the entrances 322 are each symmetrical dome shapes configured to receive (or be in close proximity to) a corresponding one of the primary lenses 210. Thus, the primary lenses 210 may protrude into the entrance geometry of the entry faces 320 and corresponding entrances 322 (of the secondary lenses 212) to capture all the light emitted out of the primary optic 210 associated therewith. However, the primary lenses 210 may be separated away therefrom and be partially disposed in the entrances 322 or positioned outside of the entrances 322 and potentially spaced away from the entry face 320 associated therewith, because the further out of the geometry of the entrance 322 that the LED component is positioned, the more light is lost at the higher angles. The entrances 322 may have other geometries, however, and need not be symmetrical. The unitary component 310 is further described with reference to FIG. 5.

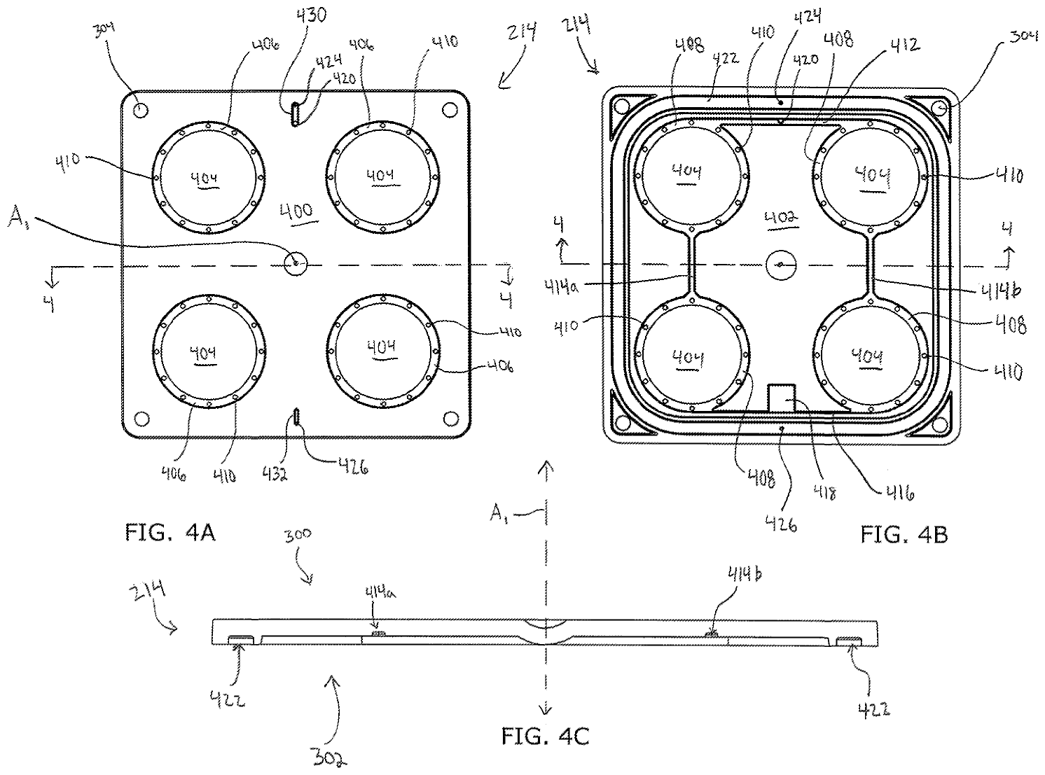

FIGS. 4A and 4B are top and bottom views, respectively, of the frame 214 of FIGS. 3A and 3B. FIG. 4C is a side cross-sectional view of the frame 214 along section line 4-4 in FIGS. 4A and 4B. In these figures, the frame 214 is illustrated without the secondary lenses 212 and the gasket 216 molded thereto. FIG. 4A illustrates an outer surface 400 of the frame 214, which corresponds with the outer side 300 of the lens assembly 104 when assembled; whereas, FIG. 4B illustrates an inner surface 402 of the frame 214, which corresponds with the inner side 302 of the lens assembly 102 when assembled.

A plurality of optic recesses or voids 404 are formed in the frame 214. The optic voids 404 extend through the frame 214, from the outer surface 400 to the inner surface 402, and are configured to receive the secondary lenses 212. In some examples, the outer surface 400 and/or the inner surface 402 of the frame 214 proximate to the optic voids 404 is recessed. In the illustrated example, the portions of the outer surface 400 surrounding the optic voids 404 is recessed (towards the inner surface 402) and thereby defines an outer optic locking runner 406 circumferentially extending around each of the optic voids 404 (FIG. 4A). Similarly, the portions of the inner surface 402 surrounding the optic voids 404 is recessed (towards the outer surface 400) and thereby defines an inner optic locking runner 408 circumferentially extending around each of the optic voids 404 (FIG. 4B). The outer and inner optic locking runners 406,408 are recessed surfaces or grooves formed into the frame 216, and together define a locking flange 409 extending circumferentially around each of the optic voids 404. As described below, material used to mold the secondary lenses 212 flows through and interlocks with the locking flange 409 to secure each of the secondary lenses 212 to the frame 216.

The frame 214 may also be configured such that components or materials molded thereto interlock with the frame 214, thus enhancing the strength at which the components or materials are secured to the frame 214. In the illustrated example, a plurality of channels 410 are formed through the frame 214. Here, the channels 410 are positioned on the locking flanges 409 proximate to a periphery of the optic voids 404 and, as shown in FIGS. 4A and 4B, extend from the outer optic locking runners 406 to the inner optic locking runners 408. In some examples, at least one of the optics voids 404 does not include either or both of the outer optic locking runners 406 and/or the inner optic locking runners 408 circumferentially extending there-around and, in these examples, channels 410 may or may not be provided about such at least one optic void 404.

The frame 214 may include an optics network of runners or pathways connecting the optic voids 404 such that a single shot of injection molded material entering the optics network via a gate or drop may form the secondary lenses 212 and the interconnecting optic runners 312 (see FIGS. 3C and 5). In the illustrated example, a first optic runner 412 is formed in the inner surface 402 of the frame 214 and defines a pathway that interconnects a first pair of the optic voids 404. Here, the first optic runner 412 is recessed (towards the inner surface 402) similar to the inner optic locking runner 408, such that the first optic runner and the inner optic locking runner 408 are substantially planar or uniform with each other. Also, a pair of second optic runners 414a,b are formed in the inner surface 402 of the frame 214 and each define a pathway that interconnects one of the first pair of the optic voids 404 with one of a second pair of the optic voids 404. In addition, a third optic runner 416 is formed in the inner surface 402 of the frame 214 and defines a pathway that interconnects the second pair of the optic voids 404. Moreover, an overflow recess 418 may be formed in the inner surface 402 of the frame 214 and connect to the third optic runner 416 at a location between the second pair of the optic voids 404. As detailed below, the overflow recess 418 may catch extra injection molding material and/or vent trapped gasses, and form a tab-like feature sometimes referred to as an optic overflow. Here, the overflow recess 418 is positioned equidistantly between the optic voids 404, but it may be positioned differently. In other examples, the overflow recess 418 may instead be positioned in connection with either of the second optic runners 414a,414b; or the overflow recess 418 may positioned in connection with both the second optic runners 414a,414b instead of the third optic runner 416; or the overflow recess 418 may positioned in connection with both the second optic runners 414a,414b and the third optic runner 416; or no overflow recess 418 may be provided at all.

As mentioned above, a gate 420 is formed to feed material into the network of runners interconnecting the optic voids 404. The gate 420, also referred to herein as an optic gate or a first gate, permits injection molding material to flow into the optics voids 404 and the interconnecting network of runners associated therewith. Here, the gate 420 is formed in the first optic runner 412 at a location therein that is equidistant between the first pair of the optic voids 404. However, the gate 420 may be provided at a different location within the first optic runner 412, or it may instead be provided at some position in either of the second optic runners 414a,414b, or it may instead be provided at some position in the third optic runner 418. In the illustrated example, injection molding material will drop from the gate 420 into the first optic runner 412, at which point the first optic runner 412 redirects or splits the flow of injection molding material towards the first pair of the optic voids 404. In addition to flowing into the optic voids 404 to form the secondary optics 212, the flow of injection molding material flows from the first optic runner 412 into the inner optic locking runners 408, and then into the outer optic locking runners 406 (FIG. 4A) via the channels 410. Thus, injection molding material will fill the first optic runner 412 and the first pair of the optic voids 404, together with the outer and inner optic locking runners 406,408 and the channels 410 associated with the first pair of the optic voids 404. The injection molding material then flows into each of the second optic runners 414a,414b, which each guide the injection molding material flowing therein towards a respective one of the second pair of optic voids 404 due to pressure exerted from the shot of injection molding material. These flows of injection molding material from the second optic runners 414a,414b enter into the inner optic locking runner 408 associated with their respective one of the second pair of optic voids 404; and then the injection molded material flows into both of the second pair of optic voids 404, and into the outer optic locking runners 406 (FIG. 4A) via the channels 410 associated therewith. Then, injection molding material will flow into opposing ends of the third optic runner 418, with each such flow of material being directed towards the over flow recess 418. Sometimes, additional injection molding material not needed to form any features of the secondary lenses 212 and the gasket 216 (or the interconnecting networks there-between) is utilized during a single shot and, in these instances, such additional material may accumulate in the over flow recess 418 to create a tab. Molding the material in this manner forms the optic runners 312, the split runner 314, the gasket overflow 316, and the optic overflow 318, as described with unitary component 310 described with reference to the FIG. 3C.

A gasket recess or void 422 is also formed in the frame 214. The gasket void 422 is configured as a mold for forming at least a portion of the gasket 216 with a single shot of injection molded material that enters the gasket network via another gate or drop 424. The gasket void 422 extends into the inner surface 402 of the frame 214, towards the outer surface 400, and is configured to receive the gasket 216. In some examples, the gasket void 422 may be configured such that the gasket 216 formed therein interlocks into or through corresponding features in the frame 214. In the illustrated example, the gasket void 422 extends along a periphery of the frame 214, defining a sealed region that will be enclosed by the gasket 216. Here, the gasket extends around all of the optic voids 404, such that the gasket 216 seals the interior 200 of the housing 102 when the LED lens assembly 104 is installed on the housing 102. However, the gasket void 422 may be routed differently on the frame 214. For example, a plurality of connected gasket voids may be formed, where each of the plurality of connected gasket voids extends around one or more of the optic voids 404, such the gasket 216 resulting from the injection molding defines two or more sealed regions that each enclose one or more of the optic voids 404.

As mentioned above, another gate 424 is formed to feed material into the gasket void 422 and network of runners associated therewith. The gate 424, also referred to herein as a gasket gate or a second gate, permits injection molding material to flow into the gasket void 422, to thereby form the gasket 216. The gate 424 may be provided at various locations within the gasket void 422 about the frame 214. Here, the gate 424 is formed at a location proximate to and in alignment with the gate 420 in the first optic runner 412. However, the gate 424 may be provided at a different location within the gasket void 422, regardless of its proximity or alignment with the gate 420. In some examples, the gates 420,424 are arranged in close proximity to each other and, in such examples, the gates 420,424 may be formed at various locations on the frame 214.

Injection molding material will drop from the gate 424 into the gasket void 422, at which point the gasket void 422 redirects and splits the flow of injection molding material in different directions about the gasket void 422. In the example illustrated in FIG. 4B, injection molding material will drop into the gasket void 422 from the gate 424, at which point the gasket void 422 divides the flow of injection molding material into clockwise and counter-clockwise flows of the injection molding material, and these opposing clockwise and counter-clockwise flows will eventually meet head on if enough injection molding material is injected during the shot. Also, an overflow gate or drop 426 may be provided to address any excess injection molding material that may accumulate during a shot and/or to allow venting of any trapped gas in the runner channels. The overflow gate 426 thus ports any excess injection molding material (and/or trapped gas) out of the gasket void 422. The overflow gate 426 may be provided at various locations within the gasket void 422 about the frame 214. Here, the overflow gate 426 is formed at a location proximate to and in alignment with the over flow recess 418 in the third optic runner 416; however, the overflow gate 426 may be provided elsewhere along the gasket void 422, regardless of symmetry.

Returning to FIG. 4A, the gates 420,424 extend through the frame 214 and define openings in the outer surface 400 of the frame 214, such that injection molding material may be inserted into the frame 214. Thus, a runner 430 configured to receive injection molding material during an injection molding process is formed in the outer surface 400 of the frame 214, and the runner 430 may be configured to feed either or both of the gates 420,424. In the illustrated example, both of the gates 420,424 are positioned in the runner 430, such that the runner 430 is a split runner configured to direct a single shot of injection molding material into both the first optic runner 412 and the gasket void 422, and thereby form the split runner 314 (see FIGS. 3C and 5). In addition, another runner may be provided in the outer surface 400 of the frame 214 to address any excess injection molding material overflow. In the illustrated example, the overflow gate 426 also opens into the outer surface 400 of the frame 214. Here, an overflow runner 432 is formed into the outer surface 400 at a location such that it encompasses the overflow gate 426. Thus, the opening of the overflow gate 426 is provided within the overflow runner 432 such that excess injection mold material and/or trapped gas is ported out of the gasket void 422, through the gate 426, and into the overflow runner 432 due to pressure. In the illustrated example, the overflow runner 432 is directed (or ported) so that it stays on the outside of the sealed area (i.e., the area enclosed by the gasket 216 within which the secondary lenses 212 are provided). As illustrated, an LSR injected into the gasket void 422 would be ported back to the outside surface 400 of the frame 214, and thus will not interfere with the ability of the gasket 216 to form a seal when ultimately utilized in an end use application.

Molding material in the manner described above will form the unitary component 310, comprising the secondary lenses 212 and the gasket 216 interconnected with the optic runners 312 and the split runner 314, together with other features such as the gasket overflow 316 and the optic overflow 318, as described with reference to the FIG. 3C. FIG. 5 is an isometric view an exit side 500 of the secondary lenses 212 and the gasket 216 molded as the unitary component 310. The exit side 500 of the unitary assembly is opposite from its entry side 308, described with reference to FIG. 3C. Thus, the exit side 500 corresponds with the outer side 300 of the lens assembly 104 when the unitary component 310 and the frame 214 are assembled together, with the secondary lenses 212 protruding outward from optic voids 404 formed in the outer surface 400 of the frame 214. FIG. 5 also provides a detailed view of one of the secondary lenses 212 and a portion of the gasket 216, according to one or more embodiments. In the detailed view, the secondary lens 212 is oriented on an axis A₂ that is parallel to axis A₁, however, in some examples, the axis A₂ may be skewed relative to axis A₁.

Each of the secondary lenses 212 includes an exit surface 502. During a molding process, material flows through the optic voids 404 in the frame 214 and cured next to a mold (not shown) to form the exit surfaces 502 of the secondary lenses 212. The exit surfaces 502 may have various geometries, and such geometries may be symmetrical or unsymmetrical. Here, each of the exit surfaces 502 has a symmetrically rounded geometry with a dimple 504 positioned at its apex. One or more of the exit surfaces 502, however, may have a different geometry, whether symmetrical or unsymmetrical, depending on the desired output illumination.

FIG. 5 also illustrates how each of the secondary lenses 212 will interlock with the frame 216 when molded. As illustrated, the secondary lenses 212 each include an outer optic locking portion 506 (formed by the outer optic locking runners 406 of the frame 214) and an inner optic locking portion 508 (formed by the inner optic locking runners 408 of the frame 214). After molding of the LED lens assembly 104, each of the outer optic locking portions 506 is disposed on the outer optic locking runners 406 and each of the inner optic locking portions 506 is disposed on the inner optic locking runners 408, such that the outer and inner optic locking portions 506,508 of each secondary lens 212 sandwiches the locking flange 409 associated therewith.

Each of the secondary lenses 212 also includes a plurality of structural portions 510 (formed by the channels 410 of the frame 214). The structural portions 510 interconnect the upper and inner locking portions 506,508 of the secondary lenses 212. After molding of the LED lens assembly 104, the structural portions 510 extend through the channels 410 in the locking flange 409 of the frame 214, thereby locking or securing the secondary lenses 212 within their optic voids 404 relative to the frame 214. Thus, the frame 214 may be configured to angle or orient the secondary lenses 212 in a desired position and maintain the secondary lenses 212 in such fixed positions.

In the illustrated example, the structural portions 510 are cylindrical structures that are positioned around the exit surface 502, radially outward from the axis A₂, and oriented approximately parallel to the axis A₂. In other examples, however, one or more of the structural portions 510 may have a different geometry, and/or be oriented differently relative to the axis A₂, and/or be positioned differently around the exit surface 502.

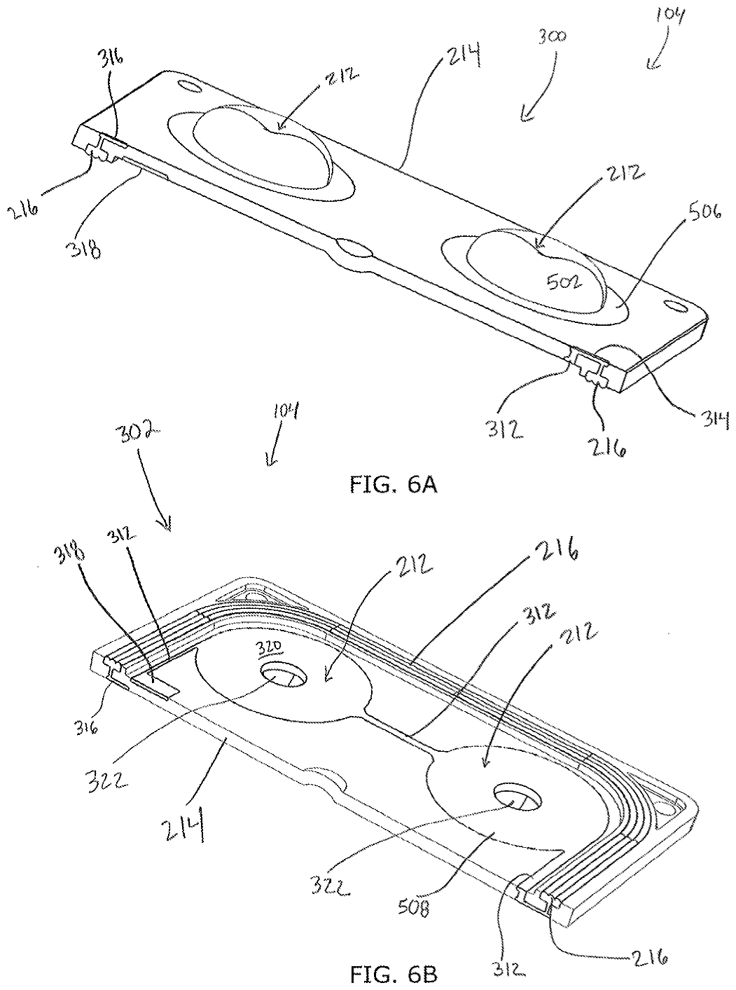

FIG. 6A is a top isometric cross-sectional view of the LED lens assembly 104 along section line 6-6 in FIG. 3A. FIG. 6B is a bottom isometric cross-sectional view of the LED lens assembly 104 along section line 6′-6′ in FIG. 3B. These figures illustrate the manner in which injection molding material cures within the frame 214 (after molding), thereby forming the secondary lenses 212 and the gasket 216 interconnected with the optic runners 312 and the split runner 314, together with other features such as the gasket overflow 316 and the optic overflow 318.

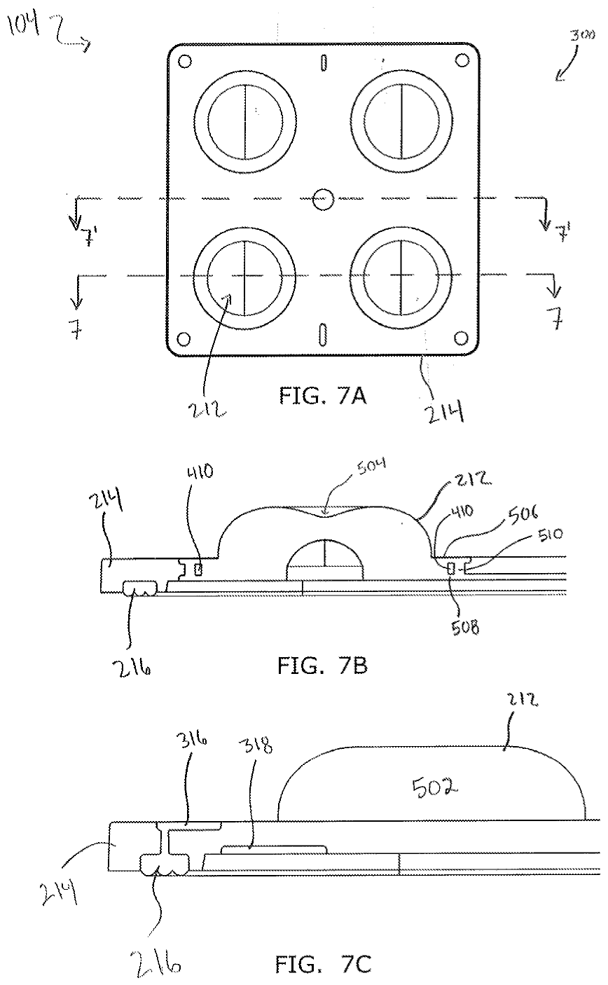

FIG. 7A is a top view of the LED lens assembly 104 of FIGS. 3A and 3B. FIG. 7B is a partial side cross-sectional view of the LED lens assembly 104 along section line 7-7 in FIG. 7A. FIG. 7C is a partial side cross-sectional view of the LED lens assembly 104 along section line 7′-7′ in FIG. 7A. FIGS. 7A-7C illustrate the manner in which injection molding material utilized to form the secondary lenses 212 and the gasket 216 will flow into and through the frame 214 and fill the various different features in the frame 214 (e.g., runner pathways, recesses, voids, etc.).

Therefore, the disclosed systems and methods are well adapted to attain the ends and advantages mentioned as well as those that are inherent therein. The particular embodiments disclosed above are illustrative only, as the teachings of the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope of the present disclosure. The systems and methods illustratively disclosed herein may suitably be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces. If there is any conflict in the usages of a word or term in this specification and one or more patent or other documents that may be incorporated herein by reference, the definitions that are consistent with this specification should be adopted.

As used herein, the phrase “at least one of” preceding a series of items, with the terms “and” or “or” to separate any of the items, modifies the list as a whole, rather than each member of the list (i.e., each item). The phrase “at least one of” allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The use of directional terms such as above, below, upper, lower, upward, downward, left, right, and the like are used in relation to the illustrative embodiments as they are depicted in the figures, the upward direction being toward the top of the corresponding figure and the downward direction being toward the bottom of the corresponding figure.

What is claimed is:

1. An LED lens assembly, comprising:
a bezel; and
a molded component comprising at least one secondary lens and a gasket, wherein the molded component is formed over the bezel with a single shot.

2. The LED lens assembly of claim 1, wherein the molded component is formed from a liquid silicone rubber material.

3. The LED lens assembly of claim 1, wherein the bezel is formed from a thermoplastic material.

4. The LED lens assembly of claim 1, wherein the at least one secondary lens is interlocking with the bezel.

5. The LED lens assembly of claim 1, wherein the at least one secondary lens includes an exit surface protruding along an axis from a void in an outer surface of the bezel.

6. The LED lens assembly of claim 5, wherein the exit surface is symmetrical about the axis along which the at least one secondary lens extends beyond the outer surface of the bezel.

7. The LED lens assembly of claim 6, wherein the exit surface includes a dimple.

8. The LED lens assembly of claim 5, wherein the bezel includes a locking flange extending around the void, and the at least one secondary lens includes an outer locking portion and an inner locking portion that sandwich the locking flange.

9. The LED lens assembly of claim 8, wherein the outer locking portion and the inner locking portion extend outward from the secondary lens, radial and perpendicular to the axis.

10. The LED lens assembly of claim 8, wherein the outer locking portion and the inner locking portion are spaced apart from each other along the axis.

11. The LED lens assembly of claim 8, wherein the outer locking portion extends radially from a base of the exit surface.

12. The LED lens assembly of claim 11, wherein the inner locking portion is spaced along the axis relative to the outer locking portion so that the outer locking portion interposes the exit surface and the inner locking portion.

13. The LED lens assembly of claim 8, wherein the at least one secondary lens includes at least one structural portion extending through the locking flange of the bezel and interconnecting the upper and inner locking portions of the secondary lens.

14. The LED lens assembly of claim 1, wherein the molded component is co-molded to the bezel.

15. The LED lens assembly of claim 1, wherein the molded component is over-molded onto the bezel.

16. The LED lens assembly of claim 1, wherein the secondary lens is optically clear.

17. A method of fabricating an LED lens assembly, comprising:
forming a frame; and
molding at least one secondary lens and a gasket to the frame, wherein the at least one secondary lens and the gasket are made of a single shot of material.

18. The method of claim 17, wherein molding the gasket and the at least one secondary lens to the frame comprises co-molding the gasket and the at least one secondary lens to the frame.

19. The method of claim 17, wherein molding the gasket and the at least one secondary lens comprises over-molding the gasket and the at least one secondary lens to the secondary lens.

20. An LED light fixture, comprising:
a housing defining an interior;
an LED light source arranged within the interior and including one or more LED chips, wherein each LED chip is encapsulated by a primary lens;
a bezel coupled to the housing; and
at least one secondary lens and a gasket molded to the bezel, wherein the at least one secondary lens and the gasket is made of a material provided in a single shot of an injection molding process.
